(19) United States
(12) Patent Application Publication
(10) Pub. No.: US 2023/0209918 A1
(43) Pub. Date: Jun. 29, 2023

(54) DISPLAY DEVICE

(71) Applicant: LG DISPLAY CO., LTD., Seoul (KR)

(72) Inventors: Dongjoo LEE, Gyeonggi-do (KR); ChangHeon KANG, Gyeonggi-do (KR)

(73) Assignee: LG DISPLAY CO., LTD., Seoul (KR)

(21) Appl. No.: 17/981,354

(22) Filed: Nov. 4, 2022

(30) Foreign Application Priority Data
Dec. 28, 2021 (KR) 10-2021-0189456

(51) Int. Cl. H01L 27/32; H01L 51/52; G06F 3/044; G06F 3/041

(52) U.S. Cl. CPC H01L 27/3258; H01L 51/5253; G06F 3/0443; G06F 3/0412; G06F 3/04164; H01L 27/323; G06F 2203/04111; G06F 2203/04103; G09G 3/2096

(57) ABSTRACT

A display device comprising a display panel is disclosed that protects against moisture and crack. The display panel is formed on a substrate and includes an open area where at least a portion of the substrate has been removed, a display area in which images are displayed and the open area is positioned, wherein in the display area, one or more subpixels each including a light emitting element and at least one transistor for driving the light emitting element are positioned on the substrate, and one or more encapsulation layers covering the light emitting element and a protection layer positioned on the one or more encapsulation layers are positioned, and a bezel area bordering at least one edge of the open area and including a non-planar pattern formed as at least a portion of at least one organic insulation film layer positioned on the substrate.

### CROSS-REFERENCE TO RELATED APPLICATION

This application claims priority from Korean Patent Application No. 10-2021-0189456, filed on Dec. 28, 2021, which is hereby incorporated by reference for all purposes as if fully set forth herein.

### BACKGROUND

### Field

Embodiments of the disclosure relate to display devices.

### Description of Related Art

With the development of technology, the display device may provide a capture function and various detection functions in addition to an image display function. To this end, the display device includes an optical electronic device (also referred to as a light receiving device or sensor), such as a camera and a detection sensor.

Since the optical electronic device receives light from the front of the display device, it should be installed where light reception is easy. Accordingly, the camera (camera lens) and the detection sensor may be exposed on a front surface of the display device. Thus, a bezel (or peripheral area) of a display panel of the display device is broadened (or widened) or a notch is formed in the display area of the display panel, and a camera or a detection sensor is installed in the broadened bezel or the notch.

When the bezel is broadened or a notch is formed in the front surface of the display panel, the display area for displaying images on the display panel may be reduced.

A “hole in active area (HiAA)”-type display device increases a display area by removing at least a portion of a substrate in the display area of the display panel and placing an electro-optical (or optical electronic) device to overlap the removed portion of the substrate.

Cracks may occur while removing a portion of the substrate, or moisture or the like may penetrate into the area where a portion of the substrate has been removed, which can deteriorate the display quality of the display device. Thus, a solution to the above problem is needed.

### BRIEF SUMMARY

Aspects of the disclosure may provide a display device that is robust against moisture permeation and cracks.

Aspects of the disclosure provides a display device, comprising a display panel, the display panel comprises a substrate, an open area where at least a portion of the substrate has been removed, a display area in which images are displayed and the open area is positioned, wherein in the display area, one or more subpixels each including a light emitting element and at least one transistor for driving the light emitting element are positioned on the substrate, and one or more encapsulation layers covering the light emitting element and a protection layer positioned on the one or more encapsulation layers are positioned, and a bezel area positioned around the open area, wherein in the bezel area, an irregularity pattern (in other words, concave-convex pattern or uneven pattern) formed as at least a portion of at least one organic insulation film layer positioned on the substrate is removed is positioned, and the protection layer is spaced apart from an edge of the open area.

According to aspects of the disclosure, there may be provided a display device that is robust against moisture permeation and cracks.

### DESCRIPTION OF DRAWINGS

The above and other objects, features, and advantages of the present disclosure will be more clearly understood from the following detailed description, taken in conjunction with the accompanying drawings, in which:

FIG. 1 is a view illustrating a system configuration of a display device according to aspects of the disclosure;

FIG. 2 is a view illustrating an equivalent circuit of a subpixel in a display panel according to aspects of the disclosure;

FIG. 3 is a cross-sectional view illustrating a display area of a display panel according to aspects of the disclosure;

FIG. 4 is a view illustrating an open area according to aspects of the disclosure;

FIG. 5 is a cross-sectional view of an HiAA bezel area of FIG. 4, taken along line I-I′;

FIG. 6 is a view illustrating, in further detail, an irregularity pattern according to aspects of the disclosure;

FIG. 7 is a view illustrating an example in which an inorganic insulation film has been removed from at least a partial area of an HiAA bezel area in a display device according to aspects of the disclosure;

FIG. 8 is a view illustrating a display area, a bending area, and a pad area in a display panel according to aspects of the disclosure;

FIG. 9 is a cross-sectional view taken along line II-II′ of FIG. 8 in a display device according to aspects of the disclosure; and

FIG. 10 is a cross-sectional view taken along line III-III′ of FIG. 8 in a display device according to aspects of the disclosure.

### DETAILED DESCRIPTION

In the following description of examples or aspects of the present disclosure, reference will be made to the accompanying drawings in which it is shown by way of illustration specific examples or aspects that can be implemented, and in which the same reference numerals and signs can be used to designate the same or like components even when they are shown in accompanying drawings different from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after” “subsequent to” “next” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various aspects of the disclosure are described in detail with reference to the accompanying drawings.

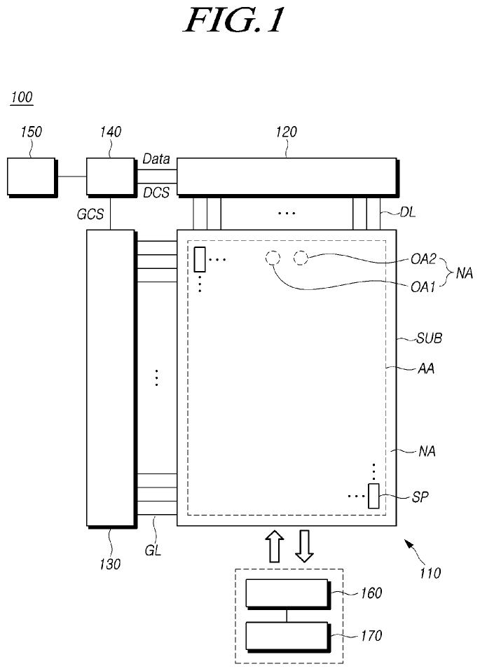

FIG. 1 is a view illustrating a system configuration of a display device 100 according to aspects of the disclosure.

Referring to FIG. 1, the display device 100 may include a display panel 110 and a display driving circuit for displaying an image.

The display driving circuit includes at least one circuit and is configured to drive the display panel 110 and may include a data driving circuit 120, a gate driving circuit 130, and a display controller 140.

The display panel 110 may include a display area AA in which images are displayed and a non-display area NA in which no image is displayed. The non-display area NA may be an area outside the display area AA and be referred to as an outer (or peripheral) bezel area. The whole or a part of the non-display area NA may be an area visible from a front surface of the display device 100 or an area that is bent and concealed from the front surface of the display device 100.

The display panel 110 may include a substrate SUB and a plurality of subpixels SP disposed on the substrate SUB. The display panel 110 may further include various types of signal lines to drive the plurality of subpixels SP.

The display device 100 according to aspects of the disclosure may be a liquid crystal display device or a light emission display device in which the display panel 110 emits light by itself. When the display device 100 according to the aspects of the disclosure is a self-emission display device, and each of the plurality of subpixels SP may include a light emitting element.

For example, the display device 100 according to aspects of the disclosure may be an organic light emitting display device in which the light emitting element is implemented as an organic light emitting diode (OLED). As another example, the display device 100 according to aspects of the disclosure may be an inorganic light emitting display device in which the light emitting element is implemented as an inorganic material-based light emitting diode. As another example, the display device 100 according to aspects of the disclosure may be a quantum dot display device in which the light emitting element is implemented as a quantum dot, which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL configured to transfer data signals (also referred to as data voltages or image signals) and a plurality of gate lines GL configured to transfer gate signals (also referred to as scan signals).

The plurality of data lines DL and the plurality of gate lines GL may cross each other. Each of the plurality of data lines DL may be disposed to extend in a first direction. Each of the plurality of gate lines GL may be disposed to extend in a second direction.

Here, the first direction may be a column direction and the second direction may be a row direction. In other examples, the first direction may be the row direction, and the second direction may be the column direction.

The data driving circuit 120 is configured to drive the plurality of data lines DL, and may output data signals to the plurality of data lines DL. The gate driving circuit 130 is configured to drive the plurality of gate lines GL, and may output gate signals to the plurality of gate lines GL.

The display controller 140 may be configured to control the operation of the data driving circuit 120 and the gate driving circuit 130. The display controller 140 may control timings for the plurality of data lines DL and timings for the plurality of gate lines GL.

The display controller 140 may supply a data control signal DCS to the data driving circuit 120 to control the data driving circuit 120. The display controller 140 may also supply a gate control signal GCS to the gate driving circuit 130 to control the gate driving circuit 130.

The display controller 140 may receive input image data from a host system 150 and supply image data Data to the data driving circuit 120 based on the input image data.

The data driving circuit 120 may supply data signals to the plurality of data lines DL according to the timing control of the display controller 140.

The data driving circuit 120 may receive digital image data Data from the display controller 140 and may convert the received image data Data into analog data signals and output the analog data signals to the plurality of data lines DL.

The gate driving circuit 130 may supply gate signals to the plurality of gate lines GL according to the timing control of the display controller 140. The gate driving circuit 130 may receive a first gate voltage corresponding to a turn-on voltage and a second gate voltage corresponding to a turn-off voltage, along with various gate control signals GCS, generate gate signals, and supply the generated gate signals to the plurality of gate lines GL.

For example, the data driving circuit 120 may be connected to the display panel 110 by a tape automated bonding (TAB) method or connected to a bonding pad of the display panel 110 by a chip on glass (COG) or chip on panel (COP) method or may be implemented by a chip on film (COF) method and connected to the display panel 110.

The gate driving circuit 130 may be connected to the display panel 110 by a TAB method or connected to a bonding pad of the display panel 110 by a COG or COP method or may be connected to the display panel 110 according to a COF method. The gate driving circuit 130 may be formed in a gate in panel (GIP) type, in the non-display area NA of the display panel 110. The gate driving circuit 130 may be disposed on the substrate SUB or may be connected to the substrate SUB. In other examples, the gate driving circuit 130 that is of a GIP type may be disposed in the non-display area NA of display panel 110. In some examples, the gate driving circuit 130 that is of a COG type or COF type may be connected to the substrate SUB.

At least one of the data driving circuit 120 and the gate driving circuit 130 may be disposed in the display area AA of the display panel 110. For example, at least one of the data driving circuit 120 and the gate driving circuit 130 may be disposed not to overlap the subpixels SP or to overlap all or some of the subpixels SP.

The data driving circuit 120 may be connected to one side (e.g., an upper or lower side) of the display panel 110. Depending on the driving method or the panel design, the data driving circuit 120 may be connected to both sides (e.g., upper and lower sides) of the display panel 110, or two or more of the four sides of the display panel 110.

The gate driving circuit 130 may be connected to one side (e.g., a left or right side) of the display panel 110. Depending on the driving method or the panel design, the gate driving circuit 130 may be connected to both sides (e.g., left and right sides) of the display panel 110, or two or more of the four sides of the display panel 110.

The display controller 140 may be implemented as a component separate from the data driving circuit 120, or the display controller 140 and the data driving circuit 120 may be integrated into an integrated circuit (IC).

The display controller 140 may include a timing controller used in display technology, a control device that may perform other control functions as well as the functions related to the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be electrically connected to the data driving circuit 120 and the gate driving circuit 130 through a printed circuit board (PCB) or a flexible printed circuit board (FPCB).

The display controller 140 may transmit/receive signals to/from the data driving circuit 120 according to one or more predetermined interfaces. The interface may include, e.g., a low voltage differential signaling (LVDS) interface, an EPI interface, and a serial peripheral interface (SPI).

Referring to FIG. 1, the display device 100 according to aspects of the disclosure may include one or more open areas (OA) where at least a portion of the substrate SUB has been removed.

One or more electro-optical devices (not shown) may be disposed in an area at least partially overlapping the open area OA. For example, the one or more electro-optical devices may include one or more of a capture device, such as a camera (e.g., an image sensor), and a detection sensor, such as a proximity sensor and an illumination sensor.

In one illustrative example, a capture device, such as a camera, may be positioned under a first open area OA1, and a detection sensor may be positioned under a second open area OA2.

The electro-optical device may be positioned under the substrate SUB. The electro-optical device may be positioned to at least partially overlap the open area OA.

The first open area OA1 and the second open area OA2 may have various shapes, such as a circle, an ellipse, a square, a hexagon, or an octagon. The shapes of the first open area OA1 and the second open area OA2 may be the same or different. The area of the first open area OA1 may be the same as or different from the area of the second open area OA2.

For convenience of description, an example in which the first open area OA1 and the second open area OA2 are circular and are identical in area is described below, but the present disclosure is not limited thereto.

At least one open area OA is positioned in the area where a portion of the substrate SUB is removed, and the open area OA may be a non-display area NA where no subpixel SP is disposed.

The open area OA positioned in the display area AA is also referred to as a hole in active area (HiAA) area.

Signal lines (e.g., data lines DL or gate lines GL) disposed on the substrate SUB may be disposed around (or bypassing) the periphery of the open area OA.

To provide a touch sensing function as well as an image display function, the display device 100 according to aspects of the disclosure may include a touch sensor and a touch sensing circuit that senses the touch sensor to detect whether a touch occurs by a touch object, such as a finger or pen, or the position of the touch.

The touch sensing circuit may include a touch driving circuit 160 that drives and senses the touch sensor and generates and outputs touch sensing data and a touch controller 170 that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit 160.

The touch sensor in the form of a touch panel may exist outside the display panel 110, or the touch sensor may exist inside the display panel 110.

When the touch panel is configured to be outside the display panel 110, the touch panel is referred to as an external touch panel. In the case of an external touch panel, the external touch panel and the display panel 110 may be separately manufactured or may be combined during an assembly process. The external touch panel may include a touch panel substrate and a plurality of touch electrodes on the touch panel substrate.

When the touch sensor is inside of or integral to the display panel 110, the touch sensor may be formed on the substrate SUB, together with signal lines and electrodes related to display driving, during the manufacturing process of the display panel 110.

The touch driving circuit 160 may supply a touch driving signal to at least one of the plurality of touch electrodes and may sense at least one of the plurality of touch electrodes to generate touch sensing data.

The touch sensing circuit may sense touch using at least one of a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen).

According to the self-capacitance sensing scheme, each of the plurality of touch electrodes may serve both as a driving touch electrode and as a sensing touch electrode. The touch driving circuit 160 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes.

According to the mutual-capacitance sensing scheme, the plurality of touch electrodes are divided into driving touch electrodes and sensing touch electrodes. The touch driving circuit 160 may drive the driving touch electrodes and sense the sensing touch electrodes.

The touch driving circuit 160 and the touch controller 170 included in the touch sensing circuit may be implemented as separate devices or as a single device. The touch driving circuit 160 and the data driving circuit 120 may be implemented as separate devices or as a single device.

The display device 100 may further include a power supply circuit for supplying various types of power to the display driving circuit and/or the touch sensing circuit.

The display device 100 according to aspects of the disclosure may be a mobile terminal, such as a smart phone or a tablet, or a monitor or television (TV) in various sizes but, without limited thereto, may be a display device in various types and various sizes capable of displaying information or images.

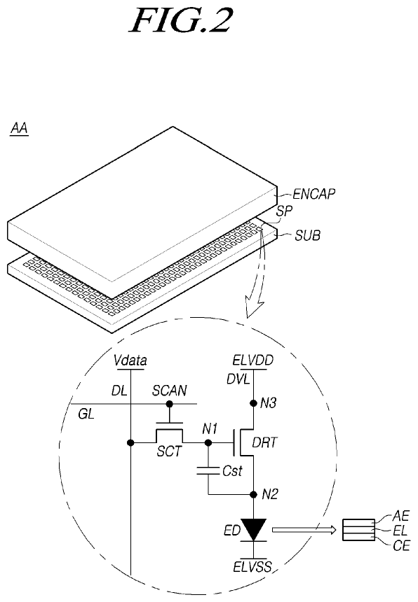

FIG. 2 is an equivalent circuit of a subpixel SP in a display panel 110 according to aspects of the disclosure.

Referring to FIG. 2, each subpixel SP in the display area AA of the display panel 110 may include a light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage for at least the duration of one frame.

The driving transistor DRT may include the first node N1 to which the data voltage Vdata may be applied, a second node N2 electrically connected to the light emitting element ED, and a third node N3 to which a high-potential common voltage ELVDD is applied from a driving voltage line DVL. The first node N1 in the driving transistor DRT may be a gate node, the second node N2 may be either a source node or a drain node, and the third node N3 may be the other of the source node and the drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor DRT of each subpixel SP. The cathode electrode CE may be a common electrode commonly disposed in the plurality of subpixels SP, and a low-potential common voltage ELVSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is presumed that the anode electrode AE is a pixel electrode and the cathode electrode CE is a common electrode.

For example, the light emitting element ED may be an OLED, an inorganic light emitting diode, or a quantum dot light emitting element. In this case, when the light emitting element ED is an OLED, the light emitting layer EL of the light emitting element ED may include an organic light emitting layer including an organic material.

In some aspects, the on/off state of the scan transistor SCT is controlled by the scan signal SCAN, which is a gate signal applied through the gate line GL. The scan transistor SCT may selectively control the electrical connection between the data line DL and the first node N1 of the driving transistor DRT.

The storage capacitor Cst may be electrically connected between the first node N1 and second node N2 of the driving transistor DRT.

Each subpixel SP may have a 2T (transistor) 1C (capacitor) structure, which includes two transistors and one capacitor as shown in FIG. 2 and, in some cases, each subpixel SP may further include one or more transistors or one or more capacitors. An example of a 2T 1C structure includes the driving transistor DRT, the scan transistor SC, and the storage capacitor Cst.

The storage capacitor Cst may be an external capacitor designed to be outside the driving transistor DRT, and does not correspond to an inherent parasitic capacitor (e.g., Cgs or Cgd) that is an internal capacitor that may be present between the first node N1 and the second node N2 of the driving transistor DRT.

Each of the driving transistor DRT and the scan transistor SCT may be an n-type transistor or a p-type transistor.

The circuit elements (particularly, the light emitting element ED) in each subpixel SP may be vulnerable to external moisture or oxygen. To protect the circuit elements, an encapsulation layer ENCAP may be disposed on the display panel 110 to prevent penetration of external moisture or oxygen into the circuit elements, such as the light emitting element ED. The encapsulation layer ENCAP may be disposed to cover the light emitting elements ED.

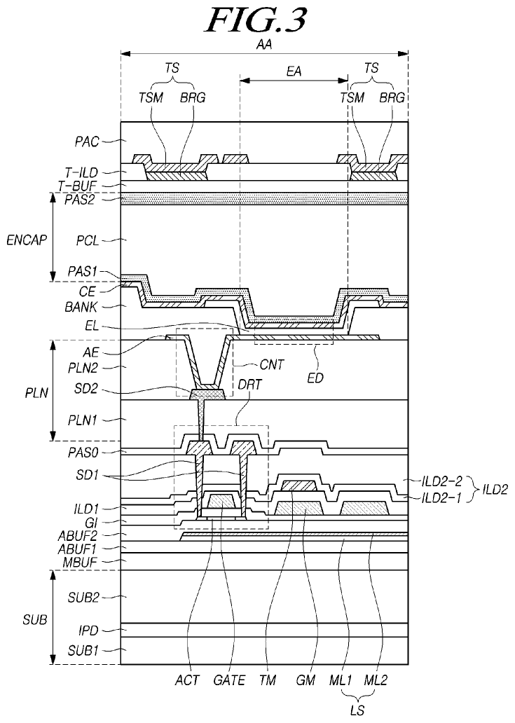

FIG. 3 is a cross-sectional view illustrating a display area AA of a display panel 110 according to aspects of the disclosure.

Referring to FIG. 3, the substrate SUB may include a first substrate SUB1, an inter-layer insulation film IPD, and a second substrate SUB2. The inter-layer insulation film IPD may be positioned between the first substrate SUB1 and the second substrate SUB2. By configuring the substrate SUB with the first substrate SUB1, the inter-layer insulation film IPD and the second substrate SUB2, it is possible to reduce or prevent moisture penetration. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Referring to FIG. 3, on the substrate SUB, various patterns (for example, active layer ACT, first source-drain electrode pattern SD1, and gate electrode GATE) may be disposed for forming a transistor, such as a driving transistor DRT, various insulation films (for example, multi-buffer layer MBUF, first active buffer layer ABUF1, second active buffer layer ABUF2, gate insulation film GI, first inter-layer insulation film ILD1, second inter-layer insulation film ILD2, and passivation layer PAS0), and various metal patterns (for example, metal pattern TM, gate material layer GM, first metal layer ML1, and second metal layer ML2).

Referring to FIG. 3, a multi-buffer layer MBUF may be disposed on the second substrate SUB2. A first active buffer layer ABUF1 may be disposed on the multi-buffer layer MBUF.

A first metal layer ML1 and a second metal layer ML2 may be disposed on the first active buffer layer ABUF1. The first metal layer ML1 and the second metal layer ML2 may be a light shield layer LS for shielding light from further penetration.

A second active buffer layer ABUF2 may be disposed on the first metal layer ML1 and the second metal layer ML2. An active layer ACT of the driving transistor DRT may be disposed on the second active buffer layer ABUF2.

Agate insulation film GI may be disposed on the second active buffer layer ABUF2 while covering the active layer ACT.

A gate electrode GATE of the driving transistor DRT may be disposed on the gate insulation film GI. In this case, a gate material layer GM, together with the gate electrode GATE of the driving transistor DRT, may be disposed on the gate insulation film GI in a different position from where the driving transistor DRT is formed.

The first inter-layer insulation film ILD1 may be disposed on the gate insulation film while covering the gate electrode GATE and the gate material layer GM. A metal pattern TM may be disposed on the first inter-layer insulation film ILD1. The metal pattern TM may be located in a position different from the position where the driving transistor DRT is formed. The second inter-layer insulation film ILD2 may be disposed on the first inter-layer insulation film ILD1 while covering the metal pattern TM.

Two first source-drain electrode patterns SD1 may be disposed on the second inter-layer insulation film ILD2. One of the two first source-drain electrode patterns SD1 is the source node of the driving transistor DRT, and the other of the two first source-drain electrode patterns SD1 is the drain node of the driving transistor DRT.

The two first source-drain electrode patterns SD1 may be electrically connected to two opposite sides of the active layer ACT through contact holes of the second inter-layer insulation film ILD2, the first inter-layer insulation film ILD1, and the gate insulation film GI.

Referring to FIG. 3, the second inter-layer insulation film ILD2 may include a 2-1th inter-layer insulation film ILD2-1 and a 2-2th inter-layer insulation film ILD2-2. The 2-1th inter-layer insulation film ILD2-1 may be positioned on the first inter-layer insulation film ILD1 while covering the metal pattern TM. The 2-2th inter-layer insulation film ILD2-2 may be positioned on the 2-1th inter-layer insulation film ILD2-1.

A portion of the active layer ACT overlaps the gate electrode GATE in a channel area. One of the two first source-drain electrode patterns SD1 may be connected to one side of the channel area in the active layer ACT, and the other one of the two first source-drain electrode patterns SD1 may be connected to the other side of the channel area in the active layer ACT.

A passivation layer PAS0 is disposed the 2-2th inter-layer insulation film ILD2-2 while covering the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the second node N2 of the driving transistor DRT in the subpixel SP of FIG. 2) through a contact hole of the first planarization layer PLN1.

The second planarization layer PLN2 may be disposed on the first planarization layer PLN1 while covering the second source-drain electrode pattern SD2. A light emitting element ED may be disposed on the second planarization layer PLN2.

In a stacked structure of the light emitting element ED, the anode electrode AE of the light emitting element ED may be disposed on the second planarization layer PLN2. The anode electrode AE may be electrically connected to the second source-drain electrode pattern SD2 through a contact hole of the second planarization layer PLN2.

A bank BANK may be disposed on the second planarization layer PLN2 while covering a portion of the anode electrode AE. A portion of the bank BANK corresponding to the light emitting area EA of the subpixel SP may be opened.

A portion of the anode electrode AE may be exposed through an opening (open portion) of the bank BANK. A light emitting layer EL may be positioned on a side surface of the bank BANK and the opening (open portion) of the bank BANK. The whole or part of the light emitting layer EL may be positioned between adjacent banks BANK.

In the opening of the bank BANK, the light emitting layer EL may contact the anode electrode AE. A cathode electrode CE may be disposed on the light emitting layer EL.

The light emitting element ED may be formed by the anode electrode AE, the light emitting layer EL, and the cathode electrode CE. The light emitting layer EL may include an organic film.

An encapsulation layer ENCAP may be disposed on the above-described light emitting element ED.

The encapsulation layer ENCAP may have a single-layer structure or a multi-layer structure. For example, as illustrated in FIG. 3, the encapsulation layer ENCAP may include a first encapsulation layer PAS1, a second encapsulation layer PCL, and a third encapsulation layer PAS2.

In another example, the first encapsulation layer PAS1 and the third encapsulation layer PAS2 may be inorganic films, and the second encapsulation layer PCL may be an organic layer. Among the first encapsulation layer PAS1, the second encapsulation layer PCL, and the third encapsulation layer PAS2, the second encapsulation layer PCL may be the thickest. Accordingly, the second encapsulation layer PCL may serve as a planarization layer. The first encapsulation layer PAS1 is also referred to as a first inorganic encapsulation layer. The second encapsulation layer PCL is also referred to as an organic encapsulation layer, and the third encapsulation layer PAS2 is also referred to as a second inorganic encapsulation layer.

The first encapsulation layer PAS1 may be disposed on the cathode electrode CE and be disposed closest to the light emitting element ED. The first encapsulation layer PAS1 may be formed of an inorganic insulating material that is capable of low-temperature deposition. For example, the first encapsulation layer PAS1 may be formed of silicon nitride (SiNx), silicon oxide (SiOx), silicon oxynitride (SiON), or aluminum oxide (Al₂O₃). Since the first encapsulation layer PAS1 is deposited in a low temperature atmosphere, the first encapsulation layer PAS1 may prevent damage to the light emitting layer EL, which includes an organic material that is vulnerable to a high temperature atmosphere associated with a deposition process.

The second encapsulation layer PCL may have a smaller area than the first encapsulation layer PAS1. In this case, the second encapsulation layer PCL may be formed to expose two opposite ends of the first encapsulation layer PAS1. The second encapsulation layer PCL serves as a buffer for relieving stress between layers due to bending of the display device 100 and may also enhance planarization performance. For example, the second encapsulation layer PCL may be an acrylic resin, an epoxy resin, polyimide, polyethylene, or silicon oxycarbon (SiOC) and be formed of an organic insulating material. For example, the second encapsulation layer PCL may be formed through an inkjet scheme.

The third encapsulation layer PAS2 may be formed on the substrate SUB, where the second encapsulation layer PCL is formed, to cover respective upper surfaces and side surfaces of the second encapsulation layer PCL and the first encapsulation layer PAS1. The third encapsulation layer PAS2 may minimize or block external moisture or oxygen from penetrating into the first encapsulation layer PAS1 and the second encapsulation layer PCL. For example, the third encapsulation layer PAS2 is formed of an inorganic insulating material, such as silicon nitride (SiNx), silicon oxide (SiOx), silicon oxynitride (SiON), or aluminum oxide (Al₂O₃).

Referring to FIG. 3, when a touch sensor TS is embedded in the display panel 110, the touch sensor TS may be disposed on the encapsulation layer ENCAP. The structure of the touch sensor is described below in detail.

A touch buffer film T-BUF may be disposed on the encapsulation layer ENCAP. A touch sensor TS may be disposed on the touch buffer film T-BUF.

The touch sensor TS may include touch sensor metals TSM and a bridge metal BRG positioned on different layers.

A touch inter-layer insulation film T-ILD may be disposed between the touch sensor metals TSM and the bridge metal BRG.

For example, the touch sensor metals TSM may include a first touch sensor metal, a second touch sensor metal, and a third touch sensor metal that are disposed adjacent to each other. The third touch sensor metal is disposed between the first touch sensor metal and the second touch sensor metal and, when the first touch sensor metal and the second touch sensor metal are electrically connected to each other, the first touch sensor metal and the second touch sensor metal may be electrically connected to each other through the bridge metal BRG, which is positioned on a layer different from that of the touch sensor metals TSM. The bridge metal BRG may be insulated from the third touch sensor metal by the touch inter-layer insulation film T-ILD. When the touch sensor TS is formed on the display panel 110, a chemical solution (e.g., developer or etchant) used in a manufacturing process of the touch sensor TS may be introduced or moisture may flow in from the outside. By disposing the touch sensor TS on the touch buffer layer T-BUF, the disclosed methods and techniques prevent a chemical solution or moisture from penetrating into the light emitting layer EL, which includes an organic material during the manufacturing process of the touch sensor TS. Thus, the touch buffer film T-BUF may prevent damage to the light emitting layer EL vulnerable to chemicals or moisture.

The touch buffer film T-BUF is formed of an organic insulation material with a low permittivity (e.g., a permittivity of 1 to 3) and is formed at a low temperature (e.g., not more than a predetermined temperature such as 100° C.) to prevent damage to the light emitting layer EL. As described above, the light emitting layer EL includes organic material that is vulnerable to high temperature. For example, the touch buffer film T-BUF may be formed of an acrylic-based, epoxy-based, or siloxan-based material. When the display device 100 is bent, the bending may damage the encapsulation layer ENCAP, and the touch sensor metal positioned on the touch buffer layer T-BUF may be broken. Even when the display device 100 is bent, the touch buffer layer T-BUF, which is formed of an organic insulating material and having planarization capability, may prevent damage to the encapsulation layer ENCAP and/or breakage of the touch sensor metals TSM and the bridge metal BRG constituting the touch sensor TS.

A protection layer PAC may be disposed on the touch inter-layer insulation film T-ILD while covering the touch sensor TS. The protection layer PAC may be an organic insulation film.

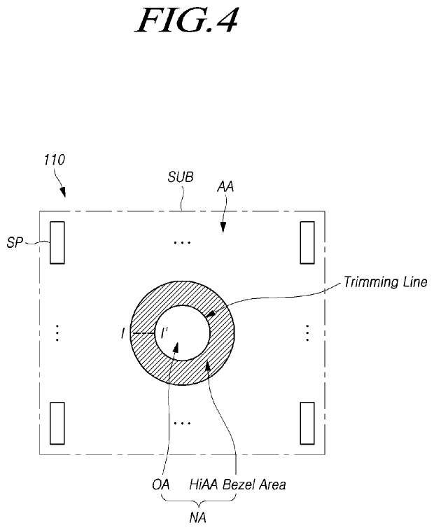

FIG. 4 is a view illustrating an open area OA in accordance with some aspects of the disclosure.

Referring to FIG. 4, the substrate SUB may be cut along a trimming line, and the cut area includes an open area OA.

A bezel area (e.g., a HiAA bezel area) is positioned around the open area OA on the substrate SUB. No subpixel is disposed in the bezel area, and the bezel area may be a non-display area NA, for example, the open area OA.

The bezel area may be configured to prevent moisture permeation that may occur along the trimming line and to prevent microcracks, which may occur while forming the open area OA, from penetrating into the display area AA.

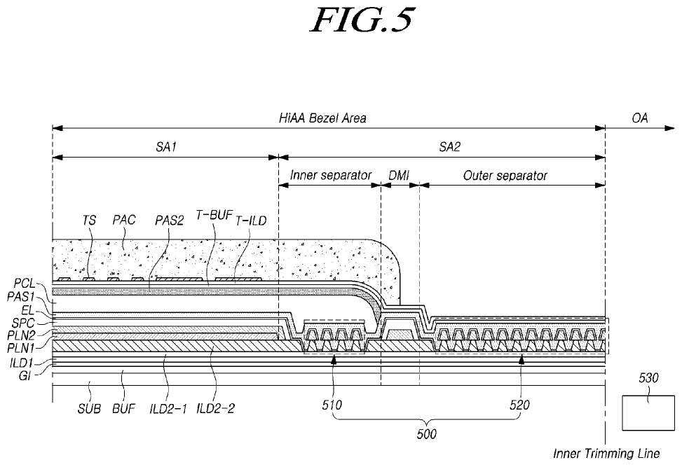

FIG. 5 is a cross-sectional view of the HiAA bezel area of FIG. 4, taken along line I-I′ in accordance with some aspects of the disclosure.

Referring to FIG. 5, an irregularity pattern 500 may be positioned on the substrate SUB in the HiAA bezel area, which is hereinafter referred to as the bezel area. In some asp[ects, the irregularity pattern 500 may be referred to as a non-planar pattern.

The irregularity pattern 500 may be formed by removing at least a portion of an organic insulation film layer (e.g., 2-2th inter-layer insulation film ILD2-2, first planarization layer PLN1, second planarization layer PLN2, etc.). For example, at least a portion of an organic insulation film layer can be etched, and a filling material can be applied to the etched regions to create a planar surface. In other aspects, deposition of a next layer can fill in the etched regions of the organic insulation film layer.

A light emitting layer EL may be positioned on the irregularity pattern 500. The light emitting layer EL is discontinuously positioned on the irregularity pattern 500. In other words, the light emitting layer EL is separated from the irregularity pattern 500. Since the irregularity pattern 500 separates the light emitting layer EL, the irregularity pattern 500 may also referred to as a separator.

A first encapsulation layer PAS1 is positioned on the light emitting layer EL in the bezel area. The first encapsulation layer PAS1 may fill valleys (e.g., local minima regions) of the irregularity pattern 500 (in other words, valleys as a part of the irregularity pattern 500).

An inner dam DMI may be positioned in the bezel area. The inner dam DMI may include at least one dam structure. The inner dam DMI may be disposed in the bezel area to prevent overflow of a second encapsulation layer PCL disposed on the first encapsulation layer PAS1 in the bezel area.

The inner dam DMI may be positioned in the irregularity pattern 500. Due to the inner dam DMI, the irregularity pattern 500 may be divided into an inner irregularity pattern 510 and an outer irregularity pattern 520.

The inner irregularity pattern 510 is positioned from the inner dam DMI to the display area AA. The outer irregularity pattern 520 is positioned from the inner dam DMI to the open area OA.

An electro-optical device 530 may be positioned to overlap at least a portion of the open area OA.

Referring to FIG. 5, the bezel area may include a first sub area (Sub Area 1: SA1) and a second sub area (Sub Area 2: SA2) positioned from the first sub area SA1 to the open area OA.

At least one touch sensor TS for touch sensing may be positioned in the first sub area SA1. The touch sensor TS may be covered with a protection layer PAC.

The above-described irregularity pattern 500 and inner dam DMI may be disposed in the second sub area SA2. The protection layer PAC may extend from the first sub area SA1 to at least a portion of the second sub area SA2.

One end of the protection layer PAC may be positioned on the inner dam DMI.

In some aspects, the protection layer PAC does not extend to the open area OA. For example, because the protection layer PAC contains an organic material, the protection layer PAC may be a path of moisture permeation. Accordingly, one end of the protection layer PAC may be positioned in the first sub area SA1 or may be positioned on the inner dam DMI as shown in FIG. 5. In some cases, one end of the protection layer PAC may be positioned on the outer irregularity pattern 520, and the protection layer PAC and the open areas OA may be spaced apart from each other.

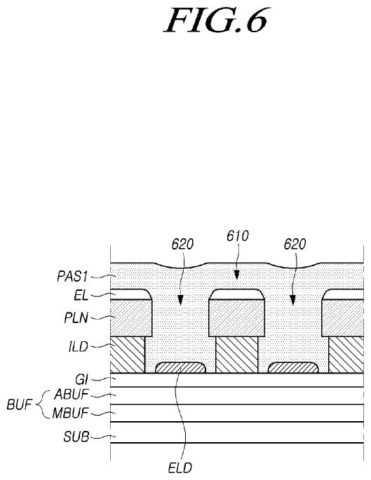

FIG. 6 is a view illustrating, in further detail, an irregularity pattern according to aspects of the disclosure.

Referring to FIG. 6, the irregularity pattern according to aspects of the disclosure may include peaks 610 (e.g., local maxima) and nadirs (e.g., local minima) 620.

The apex 610 of the irregularity pattern may include at least one organic insulation layer. For example, referring to FIG. 6, the apex 610 may include an inter-layer insulation film ILD and/or a planarization layer PLN containing an organic material.

The inter-layer insulation film ILD may include one or more of the above-described first inter-layer insulation film ILD1, 2-1th inter-layer insulation film ILD2-1, and 2-2th inter-layer insulation film ILD2-2. The planarization layer PLN may include one or more of the above-described first planarization layer PLN1 and second planarization layer PLN2.

As the apex 610 and the nadirs 620 are repeated, the light emitting layer EL is separated by the irregularity pattern, or a non-planar pattern. Accordingly, a remaining light emitting layer ELD may be positioned in the valley 620.

The light emitting layer EL, which includes the organic material, may be a path of moisture permeation. However, in FIG. 5, as the light emitting layer EL is separated by the irregularity pattern, defects in display quality due to moisture permeation can be prevented.

The irregularity pattern may be formed on the multi-buffer layer MBUF, the active buffer layer ABUF, and/or the gate insulation film GI. The multi-buffer layer MBUF, the active buffer layer ABUF, and the gate insulation film GI may be formed of an inorganic insulation film containing an inorganic material.

This inorganic insulation film may function as a crack transfer path. When a crack occurs while forming the open area by removing at least a portion of the substrate, the cracks may easily penetrate to the display area through the inorganic insulation film. In some aspects, the cracks can be prevented as further described below.

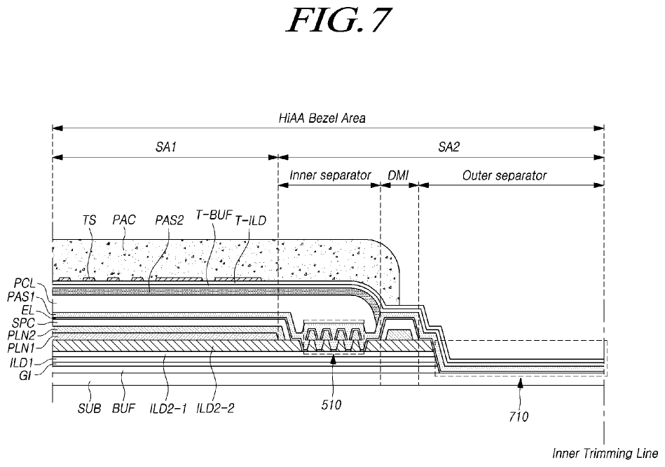

FIG. 7 is a view illustrating an example in which an inorganic insulation film has been removed from at least a partial area of an HiAA bezel area in a display device according to aspects of the disclosure.

Referring to FIG. 7, a low area 710 may be positioned in the bezel area by removing the inorganic insulation film (e.g., buffer layer BUF, gate insulation film GI, etc.) from the outside of the inner dam DMI.

In the low area 710, the organic insulation film may be removed to prevent moisture permeation, and the inorganic insulation film may be removed to prevent crack propagation.

In the low area 710, the light emitting layer EL may contact the substrate SUB. A first encapsulation layer PAS1 is positioned on the light emitting layer EL.

In some aspects, when moisture is introduced from the trimming line through the light emitting layer EL, the moisture does not reach the display area due to the inner irregularity pattern 510. Thus, display quality may further be enhanced.

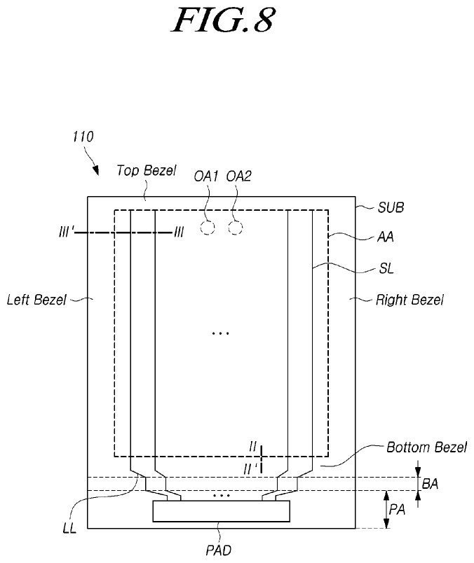

FIG. 8 is a view illustrating a display area AA, a bending area BA, and a pad area PA in the display panel 110 according to aspects of the disclosure.

Referring to FIG. 8, the display panel 110 according to aspects of the disclosure may include a display area AA and a non-display area around the display area AA.

The non-display area may include open areas OA1 and OA2, an outer bezel area, a bending area BA, and a pad area PA. The above-described HiAA bezel area is omitted from FIG. 8.

A plurality of subpixels for displaying an image are positioned in the display area AA. One or more signal lines SL are disposed in the display area AA.

The signal lines SL may include data lines for supplying data signals to the subpixels and gate lines for supplying gate signals to the subpixels.

The signal line SL shown in FIG. 8 may include a touch sensor embedded in the display panel 110. For example, a touch driving signal output from a touch driving circuit may be input to the signal line SL.

The signal line SL is assumed below to be a data line for supplying a data signal to the subpixel, but is not limited thereto.

Referring to FIG. 8, the outer bezel area is positioned around the display area AA. For example, a top bezel may be positioned above the display area AA, a left bezel may be positioned on the left side of the display area AA, a right bezel may be positioned on the right side of the display area AA, and a bottom bezel may be positioned below the display area AA.

For example, in the left and/or right bezel (area), the gate driving circuit may be disposed in a GIP type, or the gate driving circuit may be disposed in a COG type or a COF type.

In the top and/or bottom bezel (area), the data driving circuit may be connected to the display panel 110 in a TAB manner. Alternatively, in the pad portion PAD, the data driving circuit may be connected to the display panel 110 in a COG manner or a COP manner. Alternatively, the data driving circuit may be implemented in a COF fashion and be connected to the display panel 110 in the outer bezel area.

In FIG. 8, the bending area BA and the pad area PA are shown as distinguished from the bottom bezel. However, the bending area BA and the pad area PA may be included in the bottom bezel. In the disclosure, for convenience of description, the bottom bezel and the bending area BA are described as distinguished from each other, but the display device according to aspects of the disclosure is not limited thereto.

Referring to FIG. 8, the bending area BA and the pad area PA are illustrated to disclose that the pad portion PAD is positioned under the bottom bezel in accordance with some aspects of the disclosure.

The substrate constituting the display panel 110 may be bent in the bending area BA, and the pad area PA is positioned on the rear surface of the display area AA.

A plurality of link lines LL for electrically connecting the pad portion PAD and the signal line SL are disposed in the bending area BA.

In the bending area BA, the plurality of link lines LL are disposed in a direction perpendicular to a bending axis. The plurality of link lines LL may be disposed on at least one of the upper and lower sides of the bending area BA in an oblique direction inclined from a vertical direction.

The pad portion PAD may include at least one fin for transferring the signal input from the outside to the signal line SL or for transferring the signal input from the signal line SL to the outside.

For example, if the signal line SL is a data line, the pad portion PAD is connected to the data driving circuit, and the pad portion is electrically connected to the data lines of the display area AA through the plurality of link lines LL.

When the data driving circuit is positioned in a COP manner, the data driving circuit may be positioned on the pad portion PAD.

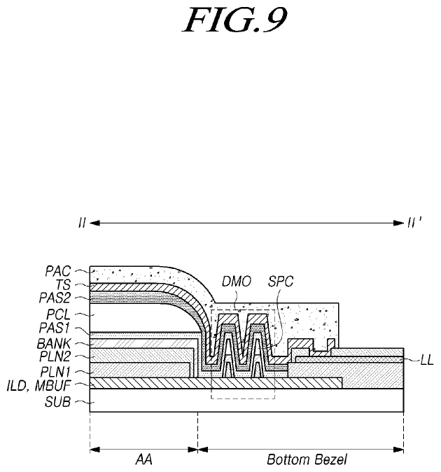

FIG. 9 is a cross-sectional view taken along line II-II′ of FIG. 8 in a display device according to aspects of the disclosure.

The inorganic insulation film layers, such as the multi-buffer layer MBUF and the inter-layer insulation film ILD positioned on the substrate SUB are shown as a single layer for simplicity. The layer may further include the above-described active buffer layer ABUF.

The inorganic insulation film layer is positioned in at least a portion of the bottom bezel. The inorganic insulation film layer may not overlap the bending area BA. Due to the characteristics of the inorganic insulation film layer, if positioned to overlap the bending area BA, the inorganic insulation film layer may be stressed, which can microcracks. Accordingly, moisture may be introduced into the inorganic insulation film layer and may permeate up to the display area AA. As a result of the moisture, the display quality may deteriorate in the display area AA. In some cases, it may be preferable that the inorganic insulation film layer be disposed not to overlap the bending area BA.

An outer dam DMO may be positioned in the bottom bezel. The outer dam DMO may include one or more dam structures. FIG. 9 illustrates examples of two dam structures, but the present disclosure is not limited thereto.

The dam structure constituting the outer dam DMO may have, e.g., a triple-layer structure including a planarization layer PLN, a bank BANK, and a spacer SPC.

The outer dam DMO may be configured to prevent the second encapsulation layer PCL positioned in the display area AA from overflowing to the bending area BA.

Referring to FIG. 9, the first encapsulation layer PAS1 and the third encapsulation layer PAS2 may extend from the display area AA and may be positioned on the dam structure of the outer dam DMO.

On the second encapsulation layer PAS2, the touch sensor TS extends from the display area AA to an area beyond the outer dam DMO. The touch sensor TS may be connected to the link line LL through a contact hole. The contact hole positioned in the area where the touch sensor TS and the link line LL are connected may be a contact hole formed in the second planarization layer PLN2.

A protection layer PAC may be positioned on the touch sensor TS, and the protection layer PAC may be positioned in at least a partial area of the display area AA and the bottom bezel.

Referring to FIG. 9, the protection layer PAC positioned on the second encapsulation layer PCL may have a step while extending from the display area AA to the bottom bezel.

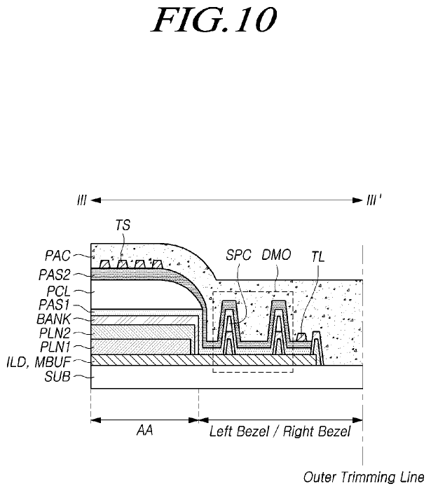

FIG. 10 is a cross-sectional view taken along line III-III′ of FIG. 8 in a display device according to aspects of the disclosure.

Referring to FIG. 10, in the display device according to aspects of the disclosure, the protection layer PAC may be disposed to extend beyond the outer dam DMO in the left bezel or the right bezel. An end of the protection layer PAC and an end of the substrate SUB may be aligned with each other in the left bezel and/or the right bezel.

A touch line TL may be configured to electrically connect the touch driving circuit and a plurality of touch sensors TS, and may be positioned outside the outer dam DMO. The protection layer PAC may be disposed to cover the touch line TL.

Accordingly, the display device according to aspects of the disclosure may provide a display device that is robust against moisture permeation and cracks.

Aspects of the disclosure may provide a display device 100 comprising a display panel, the display panel comprises a substrate SUB, an open area OA where at least a portion of the substrate SUB has been removed, a display area AA in which images are displayed and the open area OA is positioned, wherein in the display area AA, one or more subpixels SP each including a light emitting element ED and at least one transistor (e.g., the driving transistor DRT) for driving the light emitting element ED are positioned on the substrate SUB, and one or more encapsulation layers ENCAP covering the light emitting element ED and a protection layer PAC positioned on the one or more encapsulation layers are positioned, and a bezel area (HiAA bezel area) positioned around the open area OA, wherein in the bezel area (HiAA bezel area), an irregularity pattern 500 formed as at least a portion of at least one organic insulation film layer (e.g., the inter-layer insulation film ILD or planarization layer PLN) positioned on the substrate SUB is removed is positioned, and the protection layer PAC is spaced apart from an edge (corresponding to the inner trimming line of FIGS. 5 and 7) of the open area OA.

Aspects of the disclosure may provide the display device 100, wherein the light emitting element ED includes a light emitting layer EL including an organic material, wherein at least a portion of the light emitting layer EL extends up to the bezel area and is separated by the irregularity pattern 500, and wherein a remaining light emitting layer ELD is positioned in a valley 620 of the irregularity pattern 500.

Aspects of the disclosure may provide the display device 100, wherein the one or more encapsulation layers ENCAP include an inorganic encapsulation layer PAS1 contacting the light emitting layer EL in the bezel area, and wherein the inorganic encapsulation layer PAS1 covers the remaining light emitting layer ELD.

Aspects of the disclosure may provide the display device 100, wherein an inner dam DMI including at least one dam structure (corresponding to the dam structure of the inner dam DMI of FIGS. 5 and 7) is positioned in the bezel area.

Aspects of the disclosure may provide the display device 100, wherein the irregularity pattern 500 includes an inner irregularity pattern 510 and an outer irregularity pattern 520, and wherein the inner dam DMI is positioned between the inner irregularity pattern 510 and the outer irregularity pattern 520.

Aspects of the disclosure may provide the display device 100, wherein the inner dam DMI is positioned between the irregularity pattern 500 and the open area OA.

Aspects of the disclosure may provide the display device 100, wherein one or more inorganic insulation films (e.g., the multi-buffer layer MBUF, the active buffer layer ABUF, and the gate insulation film GI) positioned on the substrate SUB and under the at least one organic insulation film layer (e.g., the inter-layer insulation film ILD or planarization layer PLN) are positioned in the display area AA, and wherein the one or more inorganic insulation films are removed from an area between the inner dam DMI and the open area OA.

Aspects of the disclosure may provide the display device 100, wherein an end of the protection layer PAC is positioned on the inner dam DMI.

Aspects of the disclosure may provide the display device 100, wherein the one or more encapsulation layers ENCAP include an organic encapsulation layer PCL including an organic material, and wherein the inner dam DMI is disposed in the bezel area to prevent overflow of the organic encapsulation layer PCL.

Aspects of the disclosure may provide the display device 100, wherein the light emitting layer EL contacts the substrate SUB in at least a partial area of an area between an area where the irregularity pattern 500 is positioned and the open area OA.

Aspects of the disclosure may provide the display device 100, wherein an inorganic encapsulation layer PAS1 contacting the light emitting layer EL among the one or more encapsulation layers ENCAP extends up to the open area OA.

Aspects of the disclosure may provide the display device 100, further comprising an electro-optical device 530 positioned to overlap at least a portion of the open area OA.

Aspects of the disclosure may provide the display device 100, further comprising a plurality of touch sensors TS positioned on the substrate SUB and positioned between the one or more encapsulation layers ENCAP and the protection layer PAC, one or more touch lines TL positioned on the substrate SUB and configured to transfer a touch driving signal for touch sensing to at least one touch sensor TS among the plurality of touch sensors TS, and a touch sensing circuit sensing the at least one touch sensor TS.

Aspects of the disclosure may provide the display device 100, wherein at least one touch sensor TS among the plurality of touch sensors TS is positioned in the bezel area.

Aspects of the disclosure may provide the display device 100, wherein the protection layer PAC covers the one or more touch lines TL.

Aspects of the disclosure may provide the display device 100, wherein the irregularity pattern 500 includes an inter-layer insulation film ILD for forming the at least one transistor.

Aspects of the disclosure may provide the display device 100, wherein the irregularity pattern 500 includes a planarization layer PLN covering the at least one transistor.

Aspects of the disclosure may provide the display device 100, wherein an end of the protection layer PAC is positioned on the irregularity pattern 500.

Aspects of the disclosure may provide the display device 100, wherein the display panel 110 further comprises a left bezel positioned on the left side of the display area AA and a right bezel positioned on the right side of the display area AA, and wherein in the left bezel and/or the right bezel, an end of the protection layer PAC is aligned with an end of the substrate SUB.

Aspects of the disclosure may provide the display device 100, wherein the bezel area includes a first sub area SA1 and a second sub area SA2 positioned from the first sub area SA1 to the open area OA, wherein at least one touch sensor TS is positioned in the first sub area SA1, and the touch sensor TS is covered with a protection layer PAC, and wherein the irregularity pattern 500 and an inner dam DMI are disposed in the second sub area SA2, and the protection layer PAC extends from the first sub area SA1 to at least a portion of the second sub area SA2.

Aspects of the disclosure may provide the display device 100, wherein one end of the protection layer PAC is positioned in the first sub area SA1.

Aspects of the disclosure may provide the display device 100, wherein the irregularity pattern includes mountains 610 and valleys 620.

Aspects of the disclosure may provide the display device 100, wherein the mountain 610 of the irregularity pattern includes at least one organic insulation layer.

Aspects of the disclosure may provide the display device 100, wherein the mountain 610 includes an inter-layer insulation film ILD and/or a planarization layer PLN containing an organic material.

Aspects of the disclosure may provide the display device 100, wherein the display panel 110 further comprises a bottom bezel positioned below the display area AA and a bending area BA positioned under the bottom bezel, an inorganic insulation film layer is positioned on the substrate SUB in at least a portion of the bottom bezel, and the inorganic insulation film layer is disposed not to overlap the bending area BA.

Aspects of the disclosure may provide the display device 100, wherein an outer dam DMO is positioned in the bottom bezel, and the outer dam DMP includes one or more dam structures.

Aspects of the disclosure may provide the display device 100, wherein the dam structure constituting the outer dam DMO has a triple-layer structure including a planarization layer PLN, a bank BANK and a spacer SPC.

The above description has been presented to enable any person skilled in the art to make and use the technical idea of the present invention, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present invention. The above description and the accompanying drawings provide an example of the technical idea of the present invention for illustrative purposes only. That is, the disclosed aspects are intended to illustrate the scope of the technical idea of the present invention. Thus, the scope of the present invention is not limited to the aspects shown, but is to be accorded the widest scope consistent with the claims. The scope of protection of the present invention should be construed based on the following claims, and all technical ideas within the scope of equivalents thereof should be construed as being included within the scope of the present invention.

What is claimed is:

1. A display device that includes a display panel formed on a substrate, comprising:
an open area where at least a portion of the substrate of the display panel has been removed;
a display area in which images are displayed and the open area is positioned, wherein one or more subpixels in the display area each include a light emitting element and at least one transistor for driving the light emitting element are positioned on the substrate, and one or more encapsulation layers covering the light emitting element and a protection layer positioned on the one or more encapsulation layers; and
a bezel area bordering at least one edge of the open area and including a non-planar pattern formed as at least a portion of at least one organic insulation film layer positioned on the substrate, and the protection layer is spaced apart from the at least one edge of the open area.

2. The display device of claim 1, wherein the light emitting element includes a light emitting layer including an organic material,
wherein at least a portion of the light emitting layer extends up to the bezel area and is separated from the bezel area by the non-planar pattern, and
wherein a remaining light emitting layer is positioned in a valley of the non-planar pattern.

3. The display device of claim 2, wherein the one or more encapsulation layers include an inorganic encapsulation layer contacting the light emitting layer in the bezel area, and
wherein the inorganic encapsulation layer covers the remaining light emitting layer.

4. The display device of claim 2, wherein an inner dam including at least one dam structure is positioned in the bezel area.

5. The display device of claim 4, wherein the non-planar pattern includes an inner non-planar pattern and an outer non-planar pattern, and
wherein the inner dam is positioned between the inner non-planar pattern and the outer non-planar pattern.

6. The display device of claim 4, wherein the inner dam is positioned between the non-planar pattern and the open area.

7. The display device of claim 6, wherein one or more inorganic insulation films in the display area are positioned on the substrate and under the at least one organic insulation film layer, and
wherein the one or more inorganic insulation films are removed from an area between the inner dam and the open area.

8. The display device of claim 4, wherein an end of the protection layer is positioned to abut the inner dam.

9. The display device of claim 4, wherein the one or more encapsulation layers include an organic encapsulation layer including an organic material, and
wherein the inner dam is disposed in the bezel area to prevent overflow of the organic encapsulation layer.

10. The display device of claim 2, wherein the light emitting layer contacts the substrate in an area between an area where the non-planar pattern is positioned and the open area.

11. The display device of claim 2, wherein an inorganic encapsulation layer contacting the light emitting layer extends up to the open area.

12. The display device of claim 1, further comprising an electro-optical device positioned to overlap at least a portion of the open area.

13. The display device of claim 1, further comprising:
a plurality of touch sensors positioned on the substrate and positioned between the one or more encapsulation layers and the protection layer;
one or more touch lines positioned on the substrate and configured to transfer a touch driving signal to at least one touch sensor among the plurality of touch sensors; and
a touch sensing circuit configured to sense touch from the touch driving signal.

14. The display device of claim 13, wherein the at least one touch sensor among the plurality of touch sensors is positioned in the bezel area.

15. The display device of claim 13, wherein the protection layer covers the one or more touch lines.

16. The display device of claim 1, wherein the non-planar pattern includes an inter-layer insulation film for forming the at least one transistor.

17. The display device of claim 1, wherein the non-planar pattern includes a planarization layer covering the at least one transistor.

18. The display device of claim 1, wherein an end of the protection layer is positioned on the non-planar pattern.

19. The display device of claim 1, wherein the display panel further comprises a left bezel positioned on a left side of the display area and a right bezel positioned on a right side of the display area, and
wherein, in the left bezel and/or the right bezel, an end of the protection layer is aligned with an end of the substrate.

20. The display device of claim 1, wherein the bezel area includes a first sub area and a second sub area positioned from the first sub area to the open area,
wherein at least one touch sensor is positioned in the first sub area, and the at least one touch sensor is covered with the protection layer, and
wherein the non-planar pattern and an inner dam are disposed in the second sub area, and the protection layer extends from the first sub area to at least a portion of the second sub area.

21. The display device of claim 20, wherein an end of the protection layer is positioned in the first sub area.

22. The display device of claim 1, wherein the non-planar pattern comprises periodic local maxima regions and periodic local minima regions.

23. The display device of claim 22, wherein the local maxima regions of the non-planar pattern includes at least one organic insulation layer.

24. The display device of claim 23, wherein the local maxima regions includes an inter-layer insulation film and/or a planarization layer containing an organic material.

25. The display device of claim 1, wherein the display panel further comprises a bottom bezel positioned below the display area and a bending area positioned under the bottom bezel, wherein an inorganic insulation film layer is positioned on the substrate in at least a portion of the bottom bezel, and wherein the inorganic insulation film layer is disposed not to overlap the bending area.

26. The display device of claim 25, wherein an outer dam is positioned in the bottom bezel, and the outer dam includes one or more dam structures.

27. The display device of claim 26, wherein a dam structure constituting the outer dam has a triple-layer structure including a planarization layer, a bank and a spacer.

28. The display device of claim 1, further comprising etching at at least a portion of an organic insulation film layer to form the non-planar pattern.
